(19) United States
(12) Patent Application Publication
(10) Pub. No.: US 2024/0021570 A1
(43) Pub. Date: Jan. 18, 2024

(54) BONDING APPARATUS

(71) Applicant: ELECTRONICS AND TELECOMMUNICATIONS RESEARCH INSTITUTE, Daejeon (KR)

(72) Inventors: Jiho JOO, Daejeon (KR); Yong Sung EOM, Daejeon (KR); CHANMI LEE, Daejeon (KR); Ki Seok JANG, Daejeon (KR); GWANG-MUN CHOI, Daejeon (KR); KWANG-SEONG CHOI, Daejeon (KR); Jin Hyuk OH, Daejeon (KR)

(21) Appl. No.: 18/347,149

(22) Filed: Jul. 5, 2023

(30) Foreign Application Priority Data
Jul. 12, 2022 (KR) 10-2022-0085376
Oct. 14, 2022 (KR) 10-2022-0132231

(51) Int. Cl. H01L 23/00

(52) U.S. Cl. CPC H01L 24/75; H01L 2224/75263; H01L 2224/75343; H01L 2224/75701; H01L 2224/75702; H01L 2224/75753; H01L 2924/401

(57) ABSTRACT

Provided is a bonding apparatus. The bonding apparatus includes a stage configured to accommodate a substrate, a laser light source configured to provide laser light to devices on the substrate, and a bonding plate provided between the laser light source and the stage and configured to provide the devices on the substrate. The bonding plate includes a transparent substrate; a transparent layer below the transparent substrate; an device adhesion layer below the transparent layer and a reflective pattern provided above or below the transparent substrate and the transparent layer.

### CROSS-REFERENCE TO RELATED APPLICATIONS

This U.S. non-provisional patent application claims priority under 35 U.S.C. § 119 of Korean Patent Application Nos. 10-2022-0085376, filed on Jul. 12, 2022, and 10-2022-0132231, filed on Oct. 14, 2022, the entire contents of which are hereby incorporated by reference.

### BACKGROUND

The present disclosure herein relates to a bonding apparatus, and more particularly, to a laser bonding apparatus.

In general, a semiconductor chip or light emitting device may be mounted on a substrate by a bonding apparatus. For example, the bonding apparatus may include a thermal bonding apparatus and a laser bonding apparatus. The thermal bonding apparatus may bond the semiconductor chip or light emitting device to the substrate using heat. The laser bonding apparatus may heat the semiconductor chip or light emitting device using laser light to bond the semiconductor chip to the substrate.

### SUMMARY

The present disclosure provides a bonding apparatus capable of increasing in lifespan of a laser light source.

An embodiment of the inventive concept provides a bonding apparatus. The bonding apparatus may include: a stage configured to accommodate a substrate; a laser light source configured to provide laser light to devices on the substrate; and a bonding plate provided between the laser light source and the stage and configured to provide the devices on the substrate. The bonding plate may include: a transparent substrate; a transparent layer below the transparent substrate; an device adhesion layer below the transparent layer; and a reflective pattern provided above or below the transparent substrate and the transparent layer.

In an embodiment, the reflective pattern may include an upper reflective pattern provided above the transparent substrate.

In an embodiment, the reflective pattern may further include a lower reflective pattern aligned with the upper reflective pattern and provided below the transparent layer.

In an embodiment, the reflective pattern may further include a middle reflective pattern aligned with the upper reflective pattern and the lower reflective pattern and provided between the transparent substrate and the transparent layer.

In an embodiment, each of the lower reflective pattern and the middle reflective pattern may have a triangular cross-section.

In an embodiment, the transparent substrate may include an upper protrusion provided within the upper reflective pattern.

In an embodiment, the upper protrusion may be thicker than each of the upper reflective pattern and the device adhesion layer.

In an embodiment, the bonding apparatus may further include a camera provided on the bonding plate to align the devices below the bonding plate with the substrate.

In an embodiment, the bonding apparatus may further include a mirror provided at a side of the camera facing the laser light source to reflect the laser light to the bonding plate.

In an embodiment, the bonding apparatus may further include an optical system between the laser light source and the bonding plate. In an embodiment, the optical system may include: an optical block configured to receive the laser light from the laser light source; an concave lens between the optical block and the bonding plate; and a convex lens between the concave lens and the bonding plate.

In an embodiment of the inventive concept, a bonding apparatus includes: a stage configured to accommodate a substrate; a bonding plate provided on the stage and configured to provide devices on the substrate; a camera provided on the bonding plate; a laser light source provided at one side of the camera to provide laser light to the bonding plate; and a homogenizer provided between the camera and the bonding plate to provide the laser light to the bonding plate. In an embodiment, the bonding plate may include: a transparent substrate; a transparent layer below the transparent substrate; an device adhesion layer below the transparent layer; and a reflective pattern provided above or below the transparent substrate and the transparent layer.

In an embodiment, the bonding plate may further include an upper alignment pattern provided outside the reflective pattern and aligned with the substrate.

In an embodiment, the stage may be provided outside the substrate and have a lower alignment pattern below the upper alignment pattern.

In an embodiment, the reflective pattern may include: an upper reflective pattern provided above the transparent substrate; a lower reflective pattern aligned with the upper reflective pattern and provided below the transparent layer; and a middle reflective pattern aligned with the upper reflective pattern and the lower reflective pattern and provided between the transparent substrate and the transparent layer.

In an embodiment, the middle reflective pattern and the lower reflective pattern may be provided within the transparent substrate and the transparent layer, respectively.

In an embodiment, each of the middle reflective pattern and the lower reflective pattern may have a triangular cross-section.

In an embodiment, the middle reflective pattern may be thicker than the lower reflective pattern.

In an embodiment, the bonding apparatus may further include an ultrasonic generator connected to the stage to provide ultrasonic waves to the substrate.

In an embodiment, the bonding apparatus may further include an optical system between the laser light source and the bonding plate.

In an embodiment, the laser light source may be provided in plurality.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a cross-sectional view illustrating an example of a bonding apparatus according to an embodiment of the inventive concept;

FIG. 2 is a cross-sectional view illustrating a portion A of FIG. 1;

FIG. 3 is a plan view illustrating an example of a reflective pattern of FIG. 2;

FIG. 4 is a cross-sectional view illustrating an example of a laser light source and a bonding plate of FIG. 1;

FIG. 5 is a cross-sectional view illustrating an example of the reflective pattern of the bonding plate of FIG. 4;

FIG. 6, FIG. 7 and FIG. 8 are cross-sectional views illustrating an example of an upper reflective pattern, a middle reflective pattern, and a lower reflective pattern of FIG. 5;

FIG. 9 is a cross-sectional view illustrating an example of a transparent substrate of FIG. 5;

FIG. 10 is a cross-sectional view illustrating an example of the middle reflective pattern and the lower reflective pattern of FIG. 5;

FIG. 11 and FIG. 12 are cross-sectional views illustrating an example of a lower alignment pattern of a stage of FIG. 2;

FIG. 13 is a cross-sectional view illustrating an example of a bonding apparatus according to an embodiment of the inventive concept;

FIG. 14 and FIG. 15 are cross-sectional views illustrating an example of a bonding apparatus according to an embodiment of the inventive concept;

FIG. 16 is a cross-sectional view illustrating an example of a bonding apparatus according to an embodiment of the inventive concept; and

FIG. 17 is a cross-sectional view illustrating an example of a bonding apparatus according to an embodiment of the inventive concept.

### DETAILED DESCRIPTION

Embodiments of the present invention will be described in detail with reference to the accompanying drawings. Advantages and features of the present invention, and implementation methods thereof will be clarified through following embodiments described with reference to the accompanying drawings. The present invention may, however, be embodied in different forms and should not be construed as limited to the embodiments set forth herein. Rather, the embodiments introduced herein are provided so that the disclosed contents may be thorough and complete, and the spirit of the present invention may be sufficiently conveyed to those skilled in the art, and the present invention is only defined by the scope of the claims. Like reference numerals refer to like devices throughout.

In the following description, the technical terms are used only for explaining a specific embodiment while not limiting the present invention. In this specification, the terms of a singular form may comprise plural forms unless specifically mentioned. The meaning of ‘comprises’ and/or ‘comprising’ specifies a component, a step, an operation and/or an device does not exclude other components, steps, operations and/or devices. Since it is according to a preferred embodiment, reference numerals presented in the order of description are not necessarily limited to the order.

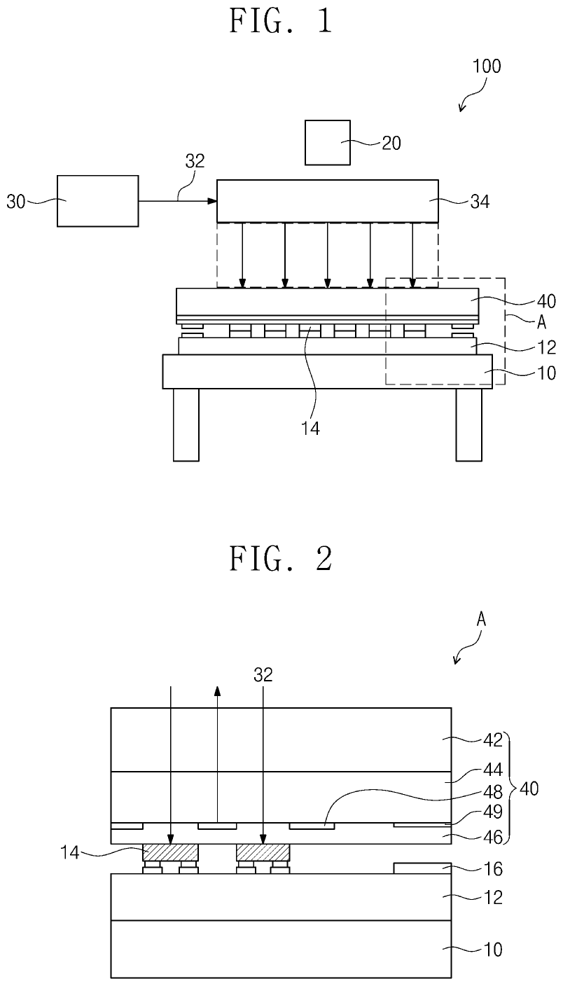

FIG. 1 is a view illustrating an example of a bonding apparatus 100 according to an embodiment of the inventive concept.

Referring to FIG. 1, the bonding apparatus 100 according to the inventive concept may include a laser bonding apparatus. According to one example, the bonding apparatus 100 according to the inventive concept may include a stage 10, a camera 20, a laser light source 30, a homogenizer 34, and a bonding plate 40.

The stage 10 may accommodate the substrate 12. The substrate 12 may include a flat plate such as glass or plastic. Alternatively, the substrate 12 may include a printed circuit board or a silicon wafer, but an embodiment of the inventive concept is not limited thereto. The substrate 12 may have upper bumps.

The camera 20 may be provided on the stage 10. The camera 20 may acquire images of the substrate 12 and devices 14 on the substrate 12 to align the devices 14 on the substrate 12.

The laser light source 30 may be provided at one side of the camera 20. The laser light source 30 may generate laser light 32. The laser light source 30 may provide the laser light 32 to the homogenizer 34.

The homogenizer 34 may be provided between the bonding plate 40 and the camera 20. The homogenizer 34 may receive the laser light 32 from the laser light source 30 to uniformly provide the laser light 32 to the bonding plate 40.

The bonding plate 40 may be provided between the stage 10 and the homogenizer 34. The bonding plate 40 may provide the devices 14 on the substrate 12. The bonding plate 40 may be transparent. The bonding plate 40 may provide the laser light 32 to the devices 14. The devices 14 may include an organic light emitting device. Alternatively, the devices 14 may include semiconductor chips, but an embodiment of the inventive concept is not limited thereto. Each of the devices 14 may have lower bumps. When the bonding plate 40 provides the devices 14 on the substrate 12, the lower bumps may be in contact with upper bumps. The laser light 32 may heat the devices 14 to bond the lower bumps to the upper bumps.

FIG. 2 is a cross-sectional view illustrating a portion A of FIG. 1.

Referring to FIG. 2, the bonding plate 40 may include a transparent substrate 42, a transparent layer 44, an device adhesion layer 46, a reflective pattern 48, and an upper alignment pattern 49.

The transparent substrate 42 may be provided on the transparent layer 44. The transparent substrate 42 may have a refractive index less than that of each of the transparent layer 44 and the device adhesion layer 46. For example, the transparent substrate 42 may include glass.

The transparent layer 44 may be provided between the transparent substrate 42 and the device adhesion layer 46. The transparent layer 44 may be thinner than the transparent substrate 42. The transparent layer 44 may have a refractive index greater than that of the transparent substrate 42 and less than that of the device adhesion layer 46. For example, the transparent layer 44 may include a plastic film.

The device adhesion layer 46 may be provided below the transparent layer 44. The device adhesion layer 46 may be thinner than the transparent layer 44. The devices 14 may adhere to the device adhesion layer 46. The device adhesion layer 46 may have a refractive index greater than that of each of the transparent substrate 42 and the transparent layer 44. For example, the device adhesion layer 46 may include epoxy. Alternatively, the device adhesion layer 46 may include a polymer, but an embodiment of the inventive concept is not limited thereto.

The reflective pattern 48 may be provided between the transparent layer 44 and the device adhesion layer 46. The reflective pattern 48 may selectively expose rear surfaces of the devices 14. The reflective pattern 48 may reflect the laser light 32. For example, the reflective pattern 48 may include aluminum.

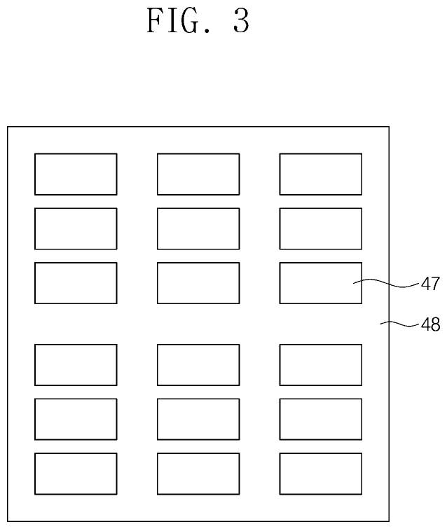

FIG. 3 is a plan view illustrating an example of the reflective pattern 48 of FIG. 2.

Referring to FIGS. 2 and 3, the reflective pattern 48 may have a plurality of holes 47. The plurality of holes 47 may selectively expose the devices 14.

Referring again to FIG. 2, the upper alignment pattern 49 may be provided between the transparent layer 44 and the device adhesion layer 46. The upper alignment pattern 49 may be disposed outside the reflective pattern 48. The upper alignment pattern 49 may be aligned with the lower alignment pattern 16 at the edge of the substrate 12. The camera 20 may acquire images of the upper alignment pattern 49 and the lower alignment pattern 16 to align the substrate 12 with the devices 14.

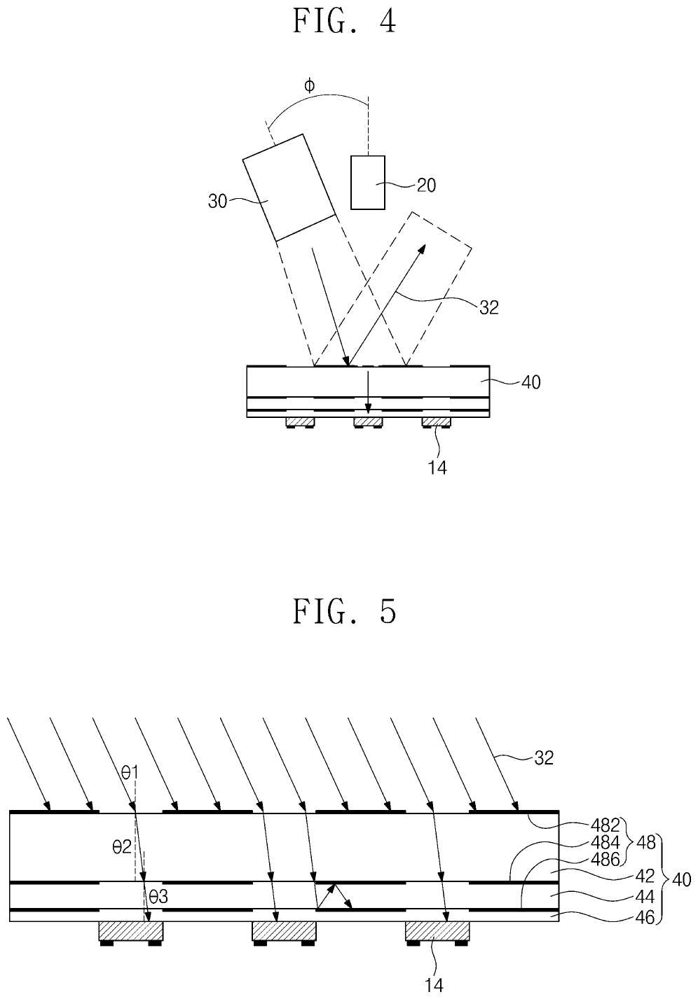

FIG. 4 is a cross-sectional view illustrating an example of the laser light source 30 and the bonding plate 40 of FIG. 1.

Referring to FIG. 4, the laser light 32 may be inclined toward the bonding plate 40. The bonding plate 40 may reflect the laser light 32 in a direction different from that of the laser light source 30 to increase in lifespan of the laser light source 30. The laser light 32 may be provided to the laser light source 30 to damage the laser light source 30. The laser light source 30 may be inclined in a direction of an azimuth angle ϕ with respect to the camera 20. The laser light 32 may be incident and/or reflected in the direction of the azimuthal angle φ with respect to the bonding plate 40.

FIG. 5 is a cross-sectional view illustrating an example of the reflective pattern 48 of the bonding plate 40 of FIG. 4.

Referring to FIG. 5, the reflective pattern 48 may include an upper reflective pattern 482, a middle reflective pattern 484, and a lower reflective pattern 486.

The upper reflective pattern 482 may be provided on the transparent substrate 42. The upper reflective pattern 482 may be provided on the middle reflective pattern 484 and the lower reflective pattern 486. The upper reflective pattern 482 may selectively expose the devices 14. The upper reflective pattern 482 may provide a portion of the laser light 32 to the transparent substrate 42 and reflect the other portion of the laser light 32. When the laser light 32 is incident at a first incident angle θ1, the transparent substrate 42 may allow the laser light 32 to proceed at a second incident angle θ2 less than the first incident angle θ1.

The middle reflective pattern 484 may be provided between the transparent substrate 42 and the transparent layer 44. The middle reflective pattern 484 may be provided between the upper reflective pattern 482 and the lower reflective pattern 486. The middle reflective pattern 484 may be aligned with the upper reflective pattern 482 and the lower reflective pattern 486. The middle reflective pattern 484 may provide a portion of the laser light 32 into the transparent layer 44 and reflect the other portion of the laser light 32. When the laser light 32 is provided to the transparent layer 44 at a second incident angle θ2, the transparent layer 44 may allow the laser light 32 to proceed at a third incident angle θ3 less than the second incident angle θ2.

The lower reflective pattern 486 may be provided between the transparent layer 44 and the device adhesion layer 46. The lower reflective pattern 486 may be provided below the middle reflective pattern 484. The lower reflective pattern 486 may be aligned with the upper reflective pattern 482 and the middle reflective pattern 484. The lower reflective pattern 486 may provide a portion of the laser light 32 into the device adhesion layer 46 and reflect the other portion of the laser light 32. Although not shown, when the laser light 32 is provided to the device adhesion layer 46 at the third incident angle θ3, the device adhesion layer 46 may allow the laser light 32 to proceed at a fourth incident angle θ4 less than the third incident angle θ3.

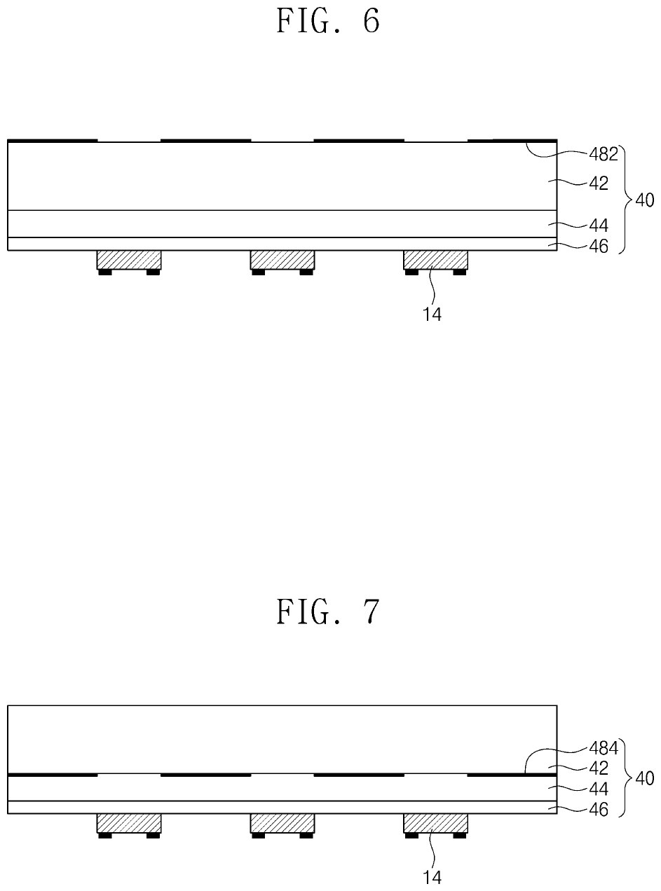

FIGS. 6 to 8 are cross-sectional views illustrating an example of the upper reflective pattern 482, the middle reflective pattern 484, and the lower reflective pattern 486 of FIG. 5.

Referring to FIGS. 6 to 8, each of the upper reflective pattern 482, the middle reflective pattern 484, and the lower reflective pattern 486 may be provided alone.

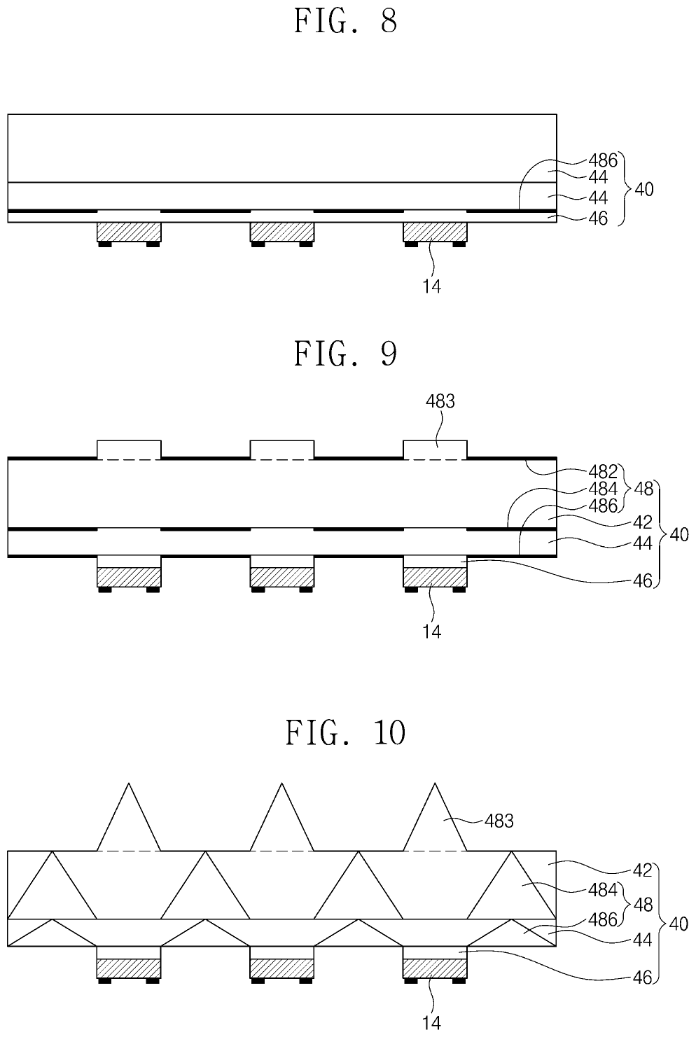

FIG. 9 is a cross-sectional view illustrating an example of the transparent substrate of FIG. 5.

Referring to FIG. 9, the transparent substrate 42 may have an upper protrusion 483. The upper protrusion 483 may be provided within the upper reflective pattern 482. Alternatively, the upper protrusion 483 may be provided between the upper reflective patterns 482. The upper protrusion 483 may be thicker than the upper reflective pattern 482. The upper protrusion 483 may be aligned with the device adhesion layer 46. In addition, the upper protrusion 483 may be thicker than the device adhesion layer 46. The device adhesion layer 46 may be provided within the lower reflective pattern 486. For example, the upper protrusion 483 may include glass or plastic. Alternatively, the upper protrusion 483 may include a polymer, but an embodiment of the inventive concept is not limited thereto.

FIG. 10 is a cross-sectional view illustrating an example of the middle reflective pattern 484 and the lower reflective pattern 486 of FIG. 5.

Referring to FIG. 10, each of the middle reflection pattern 484 and the lower reflection pattern 486 may have a triangular cross-section. The middle reflective pattern 484 may have a height greater than that of the lower reflective pattern 486. The middle reflective pattern 484 and the lower reflective pattern 486 may be provided between the upper protrusions 483. In addition, the middle reflective pattern 484 and the lower reflective pattern 486 may be provided between the device adhesion layers 46. The middle reflective pattern 484 and the lower reflective pattern 486 may focus the laser light 32 onto the devices 14.

The upper protrusion 483 may be provided between the middle reflection patterns 484. The upper protrusion 483 of the transparent substrate 42 may have the same shape as the middle reflection pattern 484 and the lower reflection pattern 486. The upper protrusion 483 may have a triangular cross-section. Although not shown, the upper protrusion 483 may have an upwardly convex lens shape, but an embodiment of the inventive concept is not limited thereto.

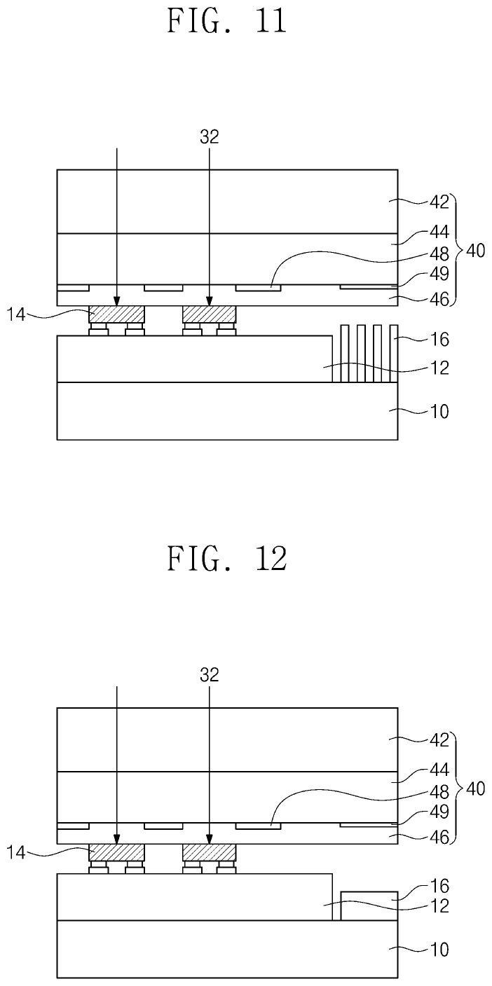

FIGS. 11 and 12 are cross-sectional views illustrating an example of a lower alignment pattern 16 of the stage of FIG. 2.

Referring to FIGS. 11 and 12, the stage 10 may have a lower alignment pattern 16 outside the substrate 12. The lower alignment pattern 16 may be provided on the edge of the stage 10. The lower alignment pattern 16 may include a plurality of unevennesses or a single block.

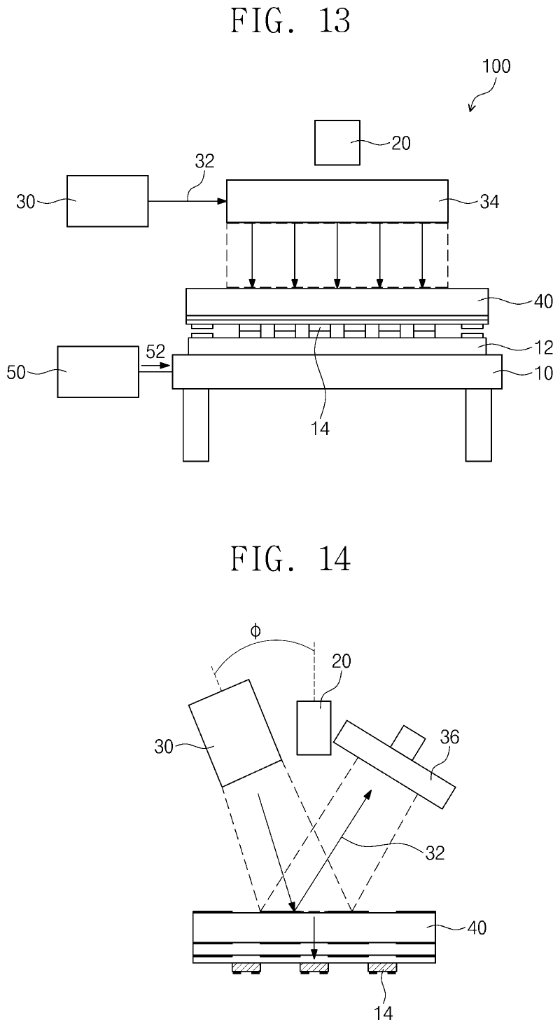

FIG. 13 is a view illustrating an example of a bonding apparatus 100 according to an embodiment of the inventive concept.

Referring to FIG. 13, the bonding apparatus 100 according to the inventive concept may further include an ultrasonic generator 50. The ultrasonic generator 50 may be connected to the stage 10. The ultrasonic generator 50 may bond the devices 14 on the substrate 12 by providing ultrasonic waves 52 to the stage 10.

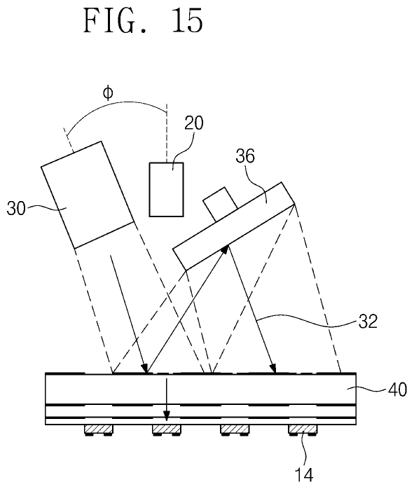

FIGS. 14 and 15 are cross-sectional views illustrating an example of a bonding apparatus 100 according to an embodiment of the inventive concept.

Referring to FIGS. 14 and 15, the bonding apparatus 100 according to the inventive concept may further include a mirror 36. The mirror 36 may be provided on the other side of the camera 20 facing the laser light source 30. The mirror 36 may improve bonding efficiency by reflecting the laser light 32 reflected from the bonding plate 40 again to the bonding plate 40.

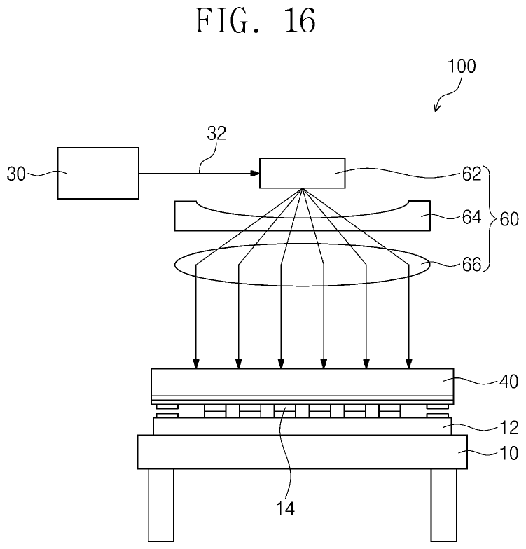

FIG. 16 is a view illustrating an example of a bonding apparatus 100 according to an embodiment of the inventive concept.

Referring to FIG. 16, the bonding apparatus 100 according to the inventive concept may further include an optical system 60. The optical system 60 may magnify the laser light 32. According to one example, the optical system 60 may include an optical block 62, a concave lens 64, and a convex lens 66.

The optical block 62 may be provided on the concave lens 64. The optical block 62 may receive the laser light 32 to provide the laser light 32 to the concave lens 64. The optical block 62 may have a rectangular cross-section.

The concave lens 64 may be provided between the optical block 62 and the convex lens 66. The concave lens 64 may magnify the laser light 32.

The convex lens 66 may be provided below the concave lens 64. The convex lens 66 may collimate the laser light 32. The laser light 32 may be provided in a direction perpendicular to the bonding plate 40 and the devices 14.

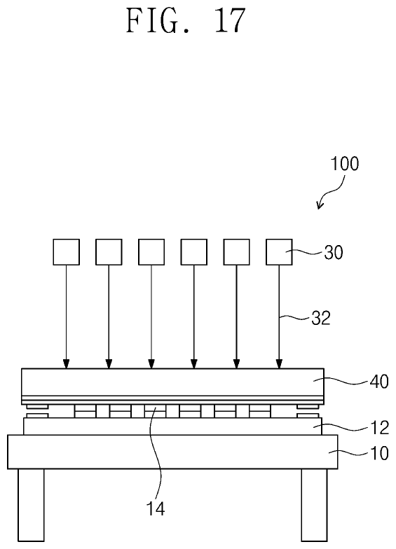

FIG. 17 is a view illustrating an example of a bonding apparatus 100 according to an embodiment of the inventive concept.

Referring to FIG. 17, the laser light source 30 of the bonding apparatus 100 according to the inventive concept may be provided in plurality. The laser light sources 30 may individually provide the laser light 32 to the devices 14 under the bonding plate 40.

As described above, the bonding apparatus according to the embodiment of the inventive concept may increase in lifespan of the laser light source by using the bonding plate having the reflective pattern and the laser light source emitting the inclined laser light to the bonding plate.

The contents described above are specific examples for carrying out the embodiment of the inventive concept. The present disclosure will include not only the embodiments described above, but also embodiments that are changeable in design or easily changed. In addition, the present disclosure will also include technologies that are capable of being easily modified and implemented in the future using the foregoing embodiments.

What is claimed is:

1. A bonding apparatus comprising:
a stage configured to accommodate a substrate;
a laser light source configured to provide laser light to devices on the substrate; and
a bonding plate provided between the laser light source and the stage and configured to provide the devices on the substrate,
wherein the bonding plate comprises:
a transparent substrate;
a transparent layer below the transparent substrate;
an device adhesion layer below the transparent layer; and
a reflective pattern provided above or below the transparent substrate and the transparent layer.

2. The bonding apparatus of claim 1, wherein the reflective pattern comprises an upper reflective pattern provided above the transparent substrate.

3. The bonding apparatus of claim 2, wherein the reflective pattern further comprises a lower reflective pattern aligned with the upper reflective pattern and provided below the transparent layer.

4. The bonding apparatus of claim 3, wherein the reflective pattern further comprises a middle reflective pattern aligned with the upper reflective pattern and the lower reflective pattern and provided between the transparent substrate and the transparent layer.

5. The bonding apparatus of claim 4, wherein each of the lower reflective pattern and the middle reflective pattern has a triangular cross-section.

6. The bonding apparatus of claim 2, wherein the transparent substrate comprises an upper protrusion provided within the upper reflective pattern.

7. The bonding apparatus of claim 6, wherein the upper protrusion is thicker than each of the upper reflective pattern and the device adhesion layer.

8. The bonding apparatus of claim 1, further comprising a camera provided on the bonding plate to align the devices below the bonding plate with the substrate.

9. The bonding apparatus of claim 8, further comprising a mirror provided at a side of the camera facing the laser light source to reflect the laser light to the bonding plate.

10. The bonding apparatus of claim 1, further comprising an optical system between the laser light source and the bonding plate,
wherein the optical system comprises:
an optical block configured to receive the laser light from the laser light source;
an concave lens between the optical block and the bonding plate; and
a convex lens between the concave lens and the bonding plate.

11. A bonding apparatus comprising:
a stage configured to accommodate a substrate;
a bonding plate provided on the stage and configured to provide devices on the substrate;
a camera provided on the bonding plate;
a laser light source provided at one side of the camera to provide laser light to the bonding plate; and
a homogenizer provided between the camera and the bonding plate to provide the laser light to the bonding plate,
wherein the bonding plate comprises:
a transparent substrate;
a transparent layer below the transparent substrate;
an device adhesion layer below the transparent layer; and
a reflective pattern provided above or below the transparent substrate and the transparent layer.

12. The bonding apparatus of claim 11, wherein the bonding plate further comprises an upper alignment pattern provided outside the reflective pattern and aligned with the substrate.

13. The bonding apparatus of claim 12, wherein the stage is provided outside the substrate and has a lower alignment pattern below the upper alignment pattern.

14. The bonding apparatus of claim 11, wherein the reflective pattern comprises:
an upper reflective pattern provided above the transparent substrate;
a lower reflective pattern aligned with the upper reflective pattern and provided below the transparent layer; and
a middle reflective pattern aligned with the upper reflective pattern and the lower reflective pattern and provided between the transparent substrate and the transparent layer.

15. The bonding apparatus of claim 14, wherein the middle reflective pattern and the lower reflective pattern are provided within the transparent substrate and the transparent layer, respectively.

16. The bonding apparatus of claim 14, wherein each of the middle reflective pattern and the lower reflective pattern has a triangular cross-section.

17. The bonding apparatus of claim 14, wherein the middle reflective pattern is thicker than the lower reflective pattern.

18. The bonding apparatus of claim 11, further comprising an ultrasonic generator connected to the stage to provide ultrasonic waves to the substrate.

19. The bonding apparatus of claim 11, further comprising an optical system between the laser light source and the bonding plate.

20. The bonding apparatus of claim 11, wherein the laser light source is provided in plurality.
